(19) United States
(12) Patent Application Publication
(10) Pub. No.: US 2012/0138337 A1
(43) Pub. Date: Jun. 7, 2012

(54) PRINTED CIRCUIT BOARD AND METHOD OF MANUFACTURING THE SAME

(75) Inventor: Eung Soo KIM, Busan (KR)

(73) Assignee: SAMSUNG ELECTRO-MECHANICS CO., LTD., Gyunggi-do (KR)

(21) Appl. No.: 13/092,065

(22) Filed: Apr. 21, 2011

(30) Foreign Application Priority Data
Dec. 6, 2010 (KR) 10-2010-0123706

(51) Int. Cl. H05K 1/02; H05K 3/10

(52) U.S. Cl. 174/250; 29/846

(57) ABSTRACT

Disclosed herein is a printed circuit board and a method of manufacturing the same, in which a bump is formed using solder paste printing, and a heat radiation layer is formed using a metal layer used in the course of forming the bump, thus simplifying the formation of the bump, reliably mounting the bump, and improving heat-radiating properties.

### CROSS REFERENCE TO RELATED ED APPLICATION

This application claims the benefit of Korean Patent Application No. 10-2010-0123706, filed Dec. 6, 2010, entitled “A method of manufacturing printed circuit board”, which is hereby incorporated by reference in its entirety into this application.

### BACKGROUND OF THE INVENTION

1. Technical Field

The present invention relates to a printed circuit board (PCB) and a method of manufacturing the same.

2. Description of the Related Art

Along with the recent advancement of electronic technology, there has been an increasing demand for electronic devices which are multi-functionalized and highly dense. However, because the area on which electronic components of a PCB of a semiconductor package can be mounted is limited, research and development into PCBs having a high degree of integration is ongoing. Normally, in order to mount an electronic component on a PCB, pads of a circuit layer are electrically connected with electrodes of the electronic component by means of bumps which are formed on the pads. In particular, in order to accurately connect electronic components which are recently being manufactured in a small size with the pads of a PCB, it is essential to form small bumps.

With reference to FIGS. 1 to 4, a method of manufacturing the PCB according to a conventional technique is described below.

As shown in FIG. 1, a PCB 11 is prepared, which includes an insulating layer 10, a circuit layer 20 formed on the insulating layer 10 and having a circuit pattern 25 and pads 23, and a solder resist layer 40 formed on the outermost surface of the PCB 11 to protect the circuit layer 20. Further, the solder resist layer 40 includes openings 47 that expose the pads 23.

Next, as shown in FIG. 2, a mask 70 is attached to the entire surface of the solder resist layer 40 having the openings 47, and portions of the mask 70 are opened so as to correspond to the openings 47 of the solder resist layer 40. Thereafter, solder bumps 60 are disposed on the pads 23 exposed by the openings 47.

Next, as shown in FIG. 3, solder bumps 60 are disposed on the pads 23, and a reflow process is performed so that the solder bumps 60 are bonded with the pads 23.

Finally, as shown in FIG. 4, the upper portions of the solder bumps 60 are subjected to coining using a press, so that the upper surfaces of the solder bumps are flattened.

However, the conventional method of forming the solder bumps 60 requires the mask 7 having open portions to dispose the solder bumps 60 on the pads 23. Furthermore, in the case where the open portions of the mask 7 do not match up with the openings 47 of the solder resist layer 40, the solder bumps 60 cannot be reliably mounted. Also, after the solder bumps 60 are reflowed, the process of coining the upper portions of the solder bumps 60 using a press is additionally required. Such an additional process may increase the number of processing steps, undesirably reducing manufacturing efficiency, and also the PCB may warp due to the pressure of the press.

In accordance with the trend of increasing the degree of integration and capacity of electronic components, heat generated from electronic components may deteriorate the performance of products. With the goal of solving heat generation problems, a process of additionally attaching a heat sink to one side of the PCB has been used. Thus, in the case where the PCB is conventionally manufactured, procedures of separately manufacturing the heat sink and attaching it to the PCB should be undesirably additionally performed.

### SUMMARY OF THE INVENTION

Accordingly, the present invention has been made keeping in mind the problems encountered in the related art and the present invention is intended to provide a PCB, in which bumps may be formed using a metal layer as a mask thus ensuring smaller bumps and improving the reliability of forming the bumps and also in which a heat radiation layer may be formed using the metal layer used in the course of forming the bumps, thus simplifying the formation of the bumps and improving heat-radiating properties, and also to provide a method of manufacturing the same.

An aspect of the present invention provides a PCB, comprising a base substrate including an insulating layer and a circuit layer which is formed on one side of the insulating layer and has a circuit pattern and a pad, a solder resist formed on one side of the base substrate, applied on the circuit layer, and having an open portion to expose the pad, a bump one end of which contacts the pad via the open portion and the other end of which is formed to protrude from the solder resist and a heat radiation layer formed along an edge of the solder resist.

In this aspect, the heat radiation layer may be formed of copper, aluminum or an aluminum alloy.

In this aspect, the bump may have a circular truncated cone shape in which a diameter increases from one end toward the other end and the other end of which is flat.

In this aspect, the other end of the bump may be formed to be flush with an exposed surface of the heat radiation layer.

Another aspect of the present invention provides a method of manufacturing a PCB, comprising (A) preparing a base substrate having an insulating layer and a circuit layer formed thereon, and stacking a solder resist and a metal layer on the base substrate, (B) forming an opening to pass through the metal layer and the solder resist so as to expose a pad of the circuit layer, (C) forming a bump in the opening and (D) selectively etching the metal layer so that the metal layer remains only on an edge of the solder resist, thus forming a heat radiation layer.

In this aspect, (A) may include (A′) preparing a base member having a metal layer and a solder resist applied thereon, preparing a base substrate having an insulating layer and a circuit layer formed thereon, and stacking the base member on the base substrate so that the solder resist and the circuit layer face each other.

In this aspect, (B) may include (B1) applying a first etching resist on the metal layer, and patterning the first etching resist so that a portion of the first etching resist corresponding to the pad is opened, (B2) selectively etching the metal layer which is exposed from the first etching resist, thus forming a window, and (B3) processing the solder resist exposed from the window thus forming an open portion, so that an opening which passes through the metal layer and the solder resist is formed.

In this aspect, the method may further comprise (B′) forming a surface treatment layer on an exposed surface of the metal layer or an exposed surface of the pad, after (B).

In this aspect, (C) may include (C1) disposing a solder paste on one side of the metal layer, and printing the solder paste toward the other side of the metal layer, thus forming the bump in the opening, and (C2) buffing the solder paste remaining on a surface of the metal layer and on a surface of the bump.

In this aspect, (D) may include (D1) applying a second etching resist on the metal layer, and patterning the second etching resist so that the second etching resist remains only on an edge of the metal layer, (D2) selectively etching the metal layer exposed from the second etching resist, thus forming a heat radiation layer, and (D3) removing the second etching resist pattern.

### BRIEF DESCRIPTION OF THE DRAWINGS

The features and advantages of the present invention will be more clearly understood from the following detailed description taken in conjunction with the accompanying drawings, in which:

FIGS. 1 to 4 are cross-sectional views sequentially showing a process of manufacturing a PCB according to a conventional technique;

FIG. 5 is a cross-sectional view showing a PCB according to the present invention;

FIG. 6 is a top plan view showing the PCB according to the present invention; and

FIGS. 7 to 16 are cross-sectional views sequentially showing a process of manufacturing the PCB according to the present invention.

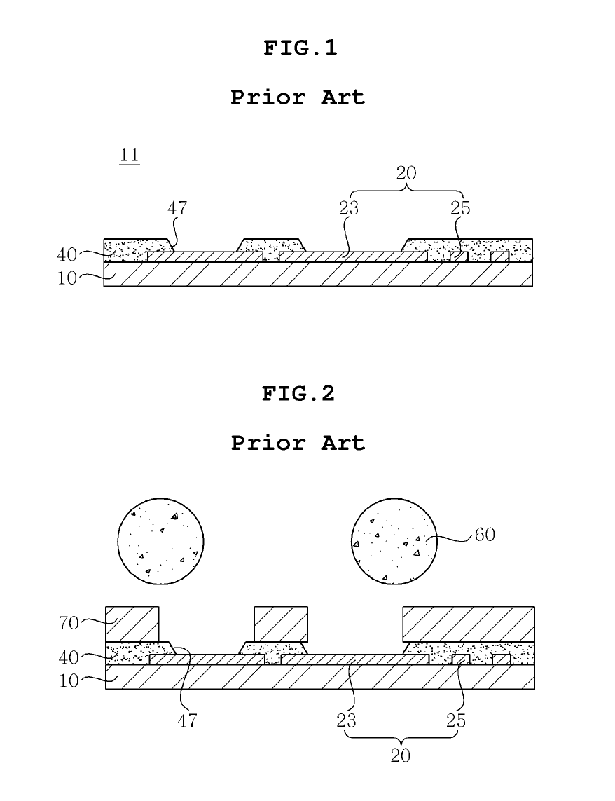

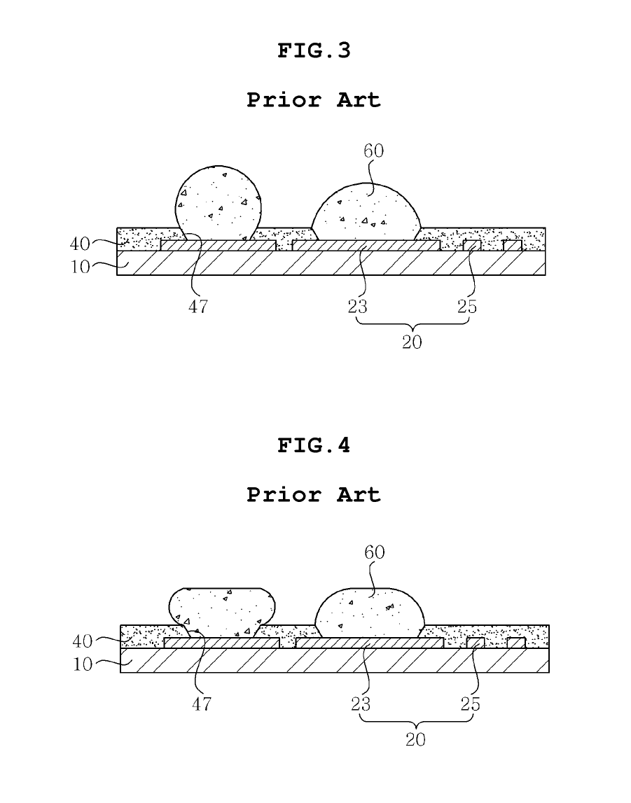

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. Moreover, descriptions of known techniques, even if they are pertinent to the present invention, are regarded as unnecessary and may be omitted when they would make the characteristics of the invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

PCB

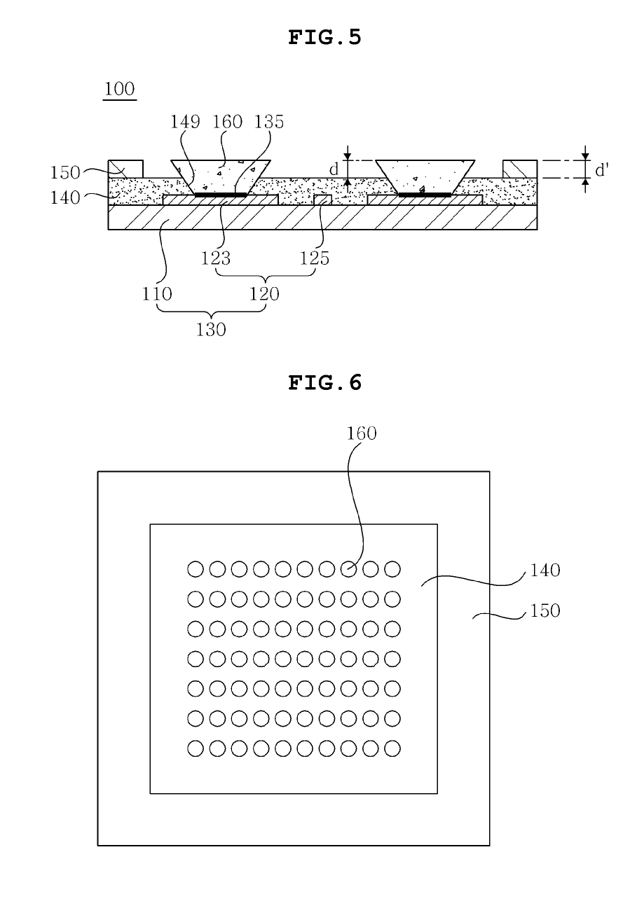

FIG. 5 is a cross-sectional view showing a PCB according to the present invention.

As shown in FIG. 5, the PCB 100 according to the present embodiment includes a base substrate 130 including an insulating layer 110 and a circuit layer 120, a solder resist 140 having open portions 149, bumps 160 formed to protrude from the solder resist 140, and a heat radiation layer 150 formed along the edge of the solder resist 140.

The base substrate 130 includes the insulating layer 110 and the circuit layer 120.

The insulating layer 110 may be formed of an insulating material typically used for a base substrate 130, for example, a composite polymer resin such as a prepreg (PPG). In addition, an epoxy resin such as FR-4, BT or the like or ABF (Ajinomoto Build-up Film) may be included, and the material of the insulating layer is not particularly limited thereto. The circuit layer 120 is formed on one side of the insulating layer 110, and includes a circuit pattern 125 and pads 123. The circuit layer 120 may be made of an electrical conductive metal such as gold, silver, copper, nickel, etc. Particularly useful is copper. In the present embodiment, a monolayer structure in which a single insulating layer 110 and a single circuit layer 120 are provided is illustrated, but a multilayer structure including a plurality of insulating layers 110 and a plurality of circuit layers 120 is possible.

The solder resist 140 is applied on one side of the base substrate 130 to thus protect the circuit layer 120. Specifically, the solder resist 140 functions to protect the circuit layer 120 so that solder is not applied on the circuit layer 120 upon soldering and also plays a role in preventing the oxidation of the circuit layer 120, and is formed of a heat resistant coating material. The solder resist 140 has open portions 149 formed at positions corresponding to the pads 123 of the circuit layer 120, and the bumps 160 are formed in the open portions 149, so that the pads 123 are electrically connected with an electronic component (not shown).

The bumps 160 are formed in the open portions 149 of the solder resist 140 so as to electrically connect the electronic component with the pads 123. Each bump 160 may function as an external connection terminal, and solder balls (not shown) are additionally formed on the bumps 160, and thus may be connected with the electronic component such as a semiconductor chip, an active device, a passive device, etc. Because the surface of the other end of each bump 160 is flat, the bumps may be easily bonded with the electronic component. Also because the bumps are wider than the diameter of the open portions 149 of the solder resist 140, in the case when the solder balls or electronic components are subjected to external force such as shear force, defects in which the solder balls or electronic components may be broken or separated may be reduced compared to the case where the surface area of the bumps 160 is small. The bumps 160 are formed in such a manner that one end of each bump 160 contacts the pad 123 and the other end thereof is formed to protrude from the solder resist 140, and the bumps 160 are provided in the form of a circular truncated cone shape in which a diameter increases from one end toward the other end. The surface of the other end of each bump 160 is formed to be flush with the surface of the heat radiation layer 150. That is, the thickness d of the protrusions (portions which protrudes from the solder resist 140) of the bumps 160 is the same as the thickness d′ of the heat radiation layer 150.

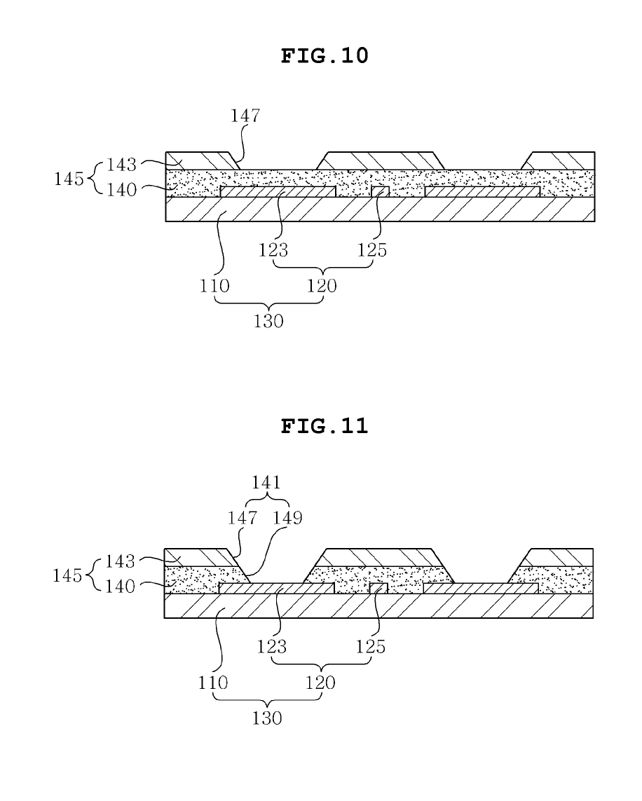

The heat radiation layer 150 is formed on the outer periphery of one side of the PCB 100 along the edge of the solder resist 140, and functions to direct heat generated from the electronic component to outside the PCB 100. The heat radiation layer 150 is formed by allowing a portion of a metal layer 143 (FIG. 10), which acts as a kind of mask formed on the solder resist 140 in order to form the bumps 160 during manufacturing of the PCB 100 according to the present embodiment, to remain on the solder resist 140. Thus, the heat radiation layer 150 is formed at the same thickness as that of the protrusions of the bumps 160. The heat radiation layer 150 may be formed of copper (Cu), aluminum (Al) or Al alloy, and the material thereof is not necessarily limited thereto. In addition, a metal having high heat conductivity such as manganese (Mg), zinc (Zn), titanium (Ti), hafnium (Hf), tantalum (Ta), or niobium (Nb) may be used.

FIG. 6 is a top plan view showing the PCB according to the present invention. As shown in FIG. 6, the plurality of bumps 160 is formed to protrude from the solder resist 140, and the heat radiation layer 150 is formed along the edge of the solder resist 140 so as to enclose the plurality of bumps 160.

Manufacturing of PCB

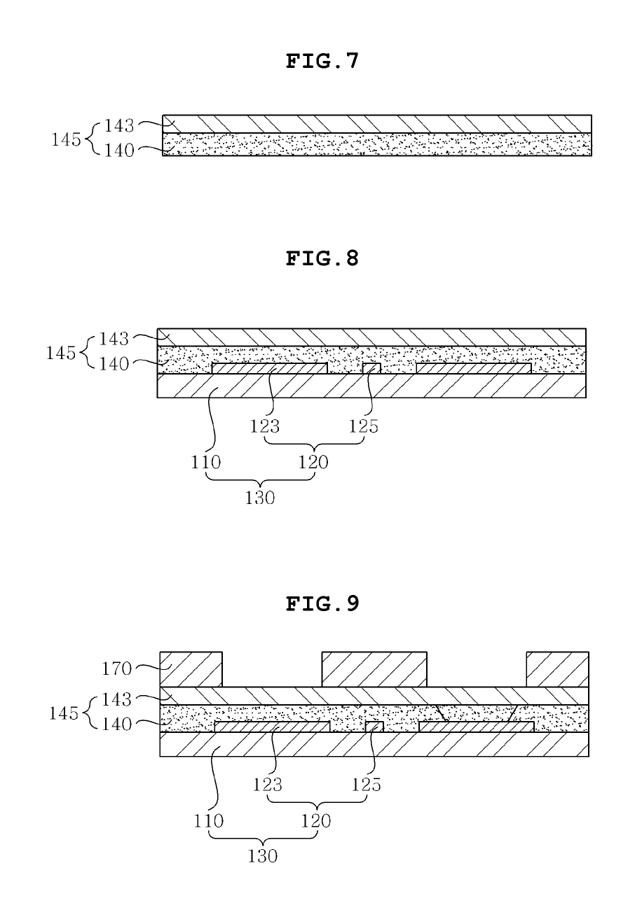

FIGS. 7 to 16 are cross-sectional views sequentially showing the process of manufacturing the PCB according to the present invention. With reference thereto, the method of manufacturing the PCB according to the present embodiment is described below.

First, as shown in FIG. 7, a base member 145 is prepared, which includes a metal layer 143 and a solder resist 140 applied thereon. The metal layer 143 functions as a mask for forming bumps 160 (FIG. 15), and as well remains as a heat radiation layer 150 (FIG. 5) on the PCB in a final structure. That is, in the course of forming the bumps 160 using solder paste printing, windows 147 (FIG. 11) are formed at positions corresponding to the open portions 149 (FIG. 11) of the solder resist 140, thus forming openings 123 (including the open portions 149 and the windows 147), thereby ensuring the thickness of the bumps 160. After the formation of the bumps, a portion of the solder resist 140 other than the edge of the solder resist 140 is selectively removed. The metal layer 143 remaining on the edge of the solder resist 140 plays a role as a heat radiation layer 150 which releases heat generated from the electronic component to outside the PCB.

Next, as shown in FIG. 8, a base substrate 130 is prepared, which includes an insulating layer 110 and a circuit layer 120 formed thereon, and the base member 145 is stacked on the base substrate 130. As such, the solder resist 140 of the base member 145 is disposed toward the side of the base substrate 130 on which the circuit layer 120 is formed. The base substrate 130 may have a monolayer structure in which a single insulating layer 110 and a single circuit layer 120 are formed, or alternatively may be provided in the form of a multilayer structure including a plurality of insulating layers 110 and a plurality of circuit layers 120.

On the other hand, the base substrate 130 and the base member 145 may be separately prepared and then stacked together, or the solder resist 140 and the metal layer 143 may be sequentially stacked on the base substrate 130.

Next, as shown in FIG. 9, a first etching resist 170 is applied on the surface of the metal layer 143, and the first etching resist 170 is patterned so that portions thereof corresponding to the pads 123 of the circuit layer 120 are opened. Specifically, the first etching resist 170 is applied on the metal layer 143 of the base substrate 130, and is then blocked by means of a mask and irradiated with UV light. Thereafter, the first etching resist 170 is exposed to a developing solution, whereby the portion cured by UV irradiation is left behind and the uncured portion is removed. The first etching resist 170 is removed after the windows 147 (FIG. 10) have been formed in the metal layer 143.

Next, as shown in FIG. 10, the metal layer 143 exposed from the first etching resist 170 is selectively etched thus forming the windows 147. The windows 147 expose the surface of the solder resist 140 applied on the direct upper portions of the pads 123. As mentioned above, the metal layer 143 may be formed of Cu, Al or Al alloy, and an etchant may be appropriately adopted depending on the type of material of the metal layer 143. The metal layer 143 functions as a kind of mask in the solder paste printing process, and the thickness of the metal layer 143 is adjusted and thereby the height of the bumps 160 may be variously set. In particular, even when bumps 160 having a narrow pitch are formed, the metal layer 143 may be thickly formed and thus the height of the bumps 160 may be increased.

Next, as shown in FIG. 11, the solder resist 140 exposed from the windows 147 is processed thus forming the open portions 149. The open portions 149 expose the surface of portions of the pads 123. The open portions 149 may be formed using a YAG laser or CO₂ laser, but the present invention is not particularly limited thereto. In the case where the solder resist 140 is processed using a laser, application of a resist, photo-exposure and development may be omitted, thus reducing the process time and cost. As well, the open portions 149 formed using a laser have a tapered inner wall. In this case, because the contact area between the solder paste and the solder resist 140 is increased, the bumps 160 may be securely adhered to the solder resist 140. Thereafter, desmearing is performed so that burrs or metal particles are removed from the inner wall of the openings 141.

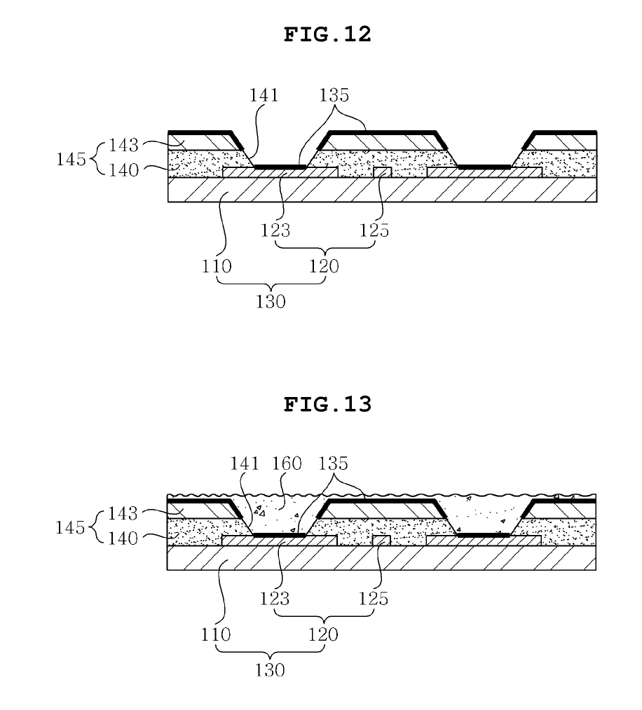

Next, as shown in FIG. 12, a surface treatment layer 135 is formed on the exposed surface of the metal layer 143 or the exposed surface of the pads 123. The surface treatment layer 135 is formed using electroplating and functions to prevent the oxidation of the exposed pads 123, improve the solderability of the mounted electronic component and impart high conductivity. As such, the material of the surface treatment layer 135 may be Ni or Cu.

Next, as shown in FIG. 13, the solder paste is disposed on one side of the metal layer 143, and the solder paste is printed toward the other side of the metal layer 143, thus forming the bumps 160 in the openings 141. In the present invention, the printing of the solder paste using the metal layer 143 as a mask is adopted. As such, the printing process is the same as a typically used screen printing process. Specifically, the solder paste is pushed through the openings 141 by means of a squeegee and is thus transferred onto the pads 123, thus making it possible to be printed at a desired shape and height. Because the openings 141 have a tapered inner wall, the amount of solder paste that is applied may be increased and the adhesion of the solder paste may be enhanced.

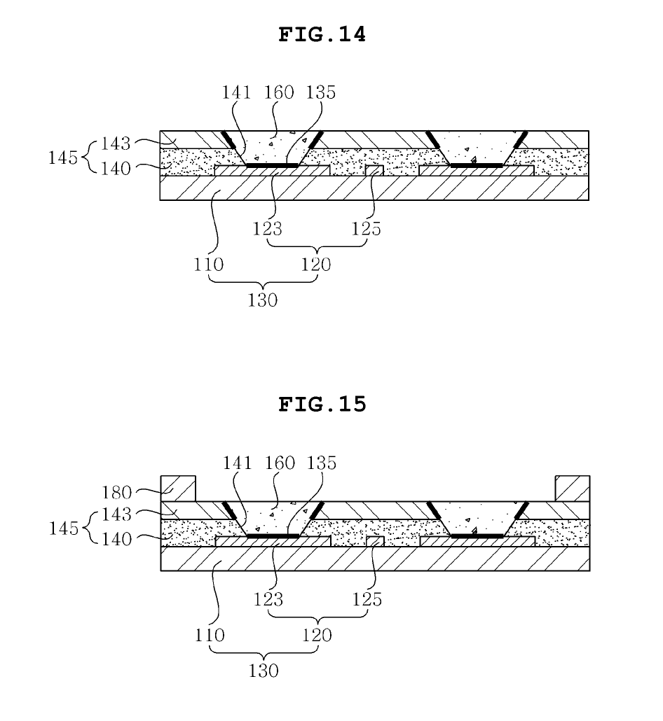

Next, as shown in FIG. 14, the solder paste remaining on the surface of the metal layer 143 and the surface of the bumps 160 is subjected to buffing to flatten their surfaces. The buffing process helps to make the height of the bumps 160 uniform, and the surface of the other end of bumps 160 may be formed to be flush with the exposed surface 143 of the metal layer. The buffing process may be performed using mechanical polishing. A polishing machine used for mechanical polishing may include a ceramic buff or a belt sander, but is not necessarily limited thereto, and other machines and devices having the same functions and actions may be used.

Next, as shown in FIG. 15, a second etching resist 180 is formed on the edge of the metal layer 143. The second etching resist 180 is applied on the metal layer 143, and then blocked by means of a mask and irradiated with UV light. Whereas a portion of the second etching resist 180 at the edge of the metal layer 143 is cured, the other portion of the second etching resist 180 is not cured. Thereafter, the second etching resist 180 is exposed to a developing solution, so that only the uncured second etching resist 180 is left behind on the edge of the metal layer 143.

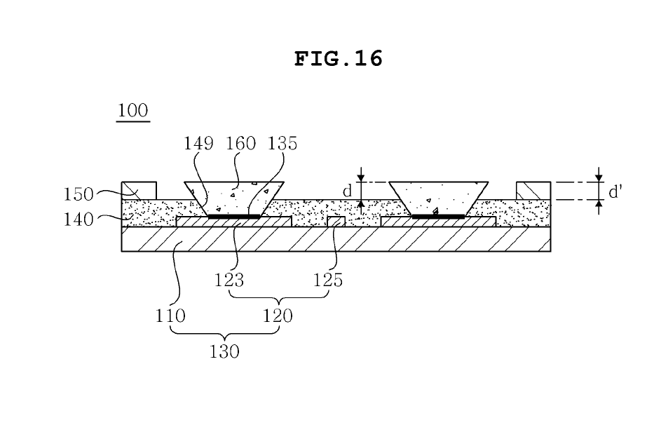

Next, as shown in FIG. 16, the metal layer 143 is selectively etched and removed so that the metal layer 143 remains only on the edge of the solder resist 140. Thereafter, the second etching resist 180 is removed from the metal layer 143 thus forming the heat radiation layer 150. In the present invention, the heat radiation layer 150 is formed using the metal layer 143 which remains on the solder resist 140 without being removed using etching. As such, not only the metal layer 143 which is not exposed to the etchant by the second etching resist 180, but also the bumps 160 formed in the openings 141 are not removed but are left behind.

As described hereinbefore, the present invention provides a PCB and a method of manufacturing the same. According to the present invention, bumps can be formed smaller by using a metal layer as a mask.

Also, according to the present invention, a solder resist and a metal layer are processed simultaneously thus forming openings, whereby the degree of matching between the solder resist and the metal layer can increase, thus maximizing the yield of forming bumps.

Also, according to the present invention, a portion of the metal layer used in the course of forming bumps is used as a heat radiation layer, thus obviating the need to attach an additional heat sink, whereby a PCB having improved heat-radiating properties can be more effectively manufactured.

Also, according to the present invention, there is no need to additionally perform a coining process for flattening the upper surface of bumps, thus solving warping problems of the PCB.

Although the embodiments of the present invention regarding the PCB and the method of manufacturing the same have been disclosed for illustrative purposes, those skilled in the art will appreciate that a variety of different modifications, additions and substitutions are possible, without departing from the scope and spirit of the invention as disclosed in the accompanying claims Accordingly, such modifications, additions and substitutions should also be understood as falling within the scope of the present invention.

What is claimed is:

1. A printed circuit board, comprising:
a base substrate including an insulating layer and a circuit layer which is formed on one side of the insulating layer and has a circuit pattern and a pad;
a solder resist formed on one side of the base substrate, applied on the circuit layer, and having an open portion to expose the pad;
a bump one end of which contacts the pad via the open portion and the other end of which is formed to protrude from the solder resist; and
a heat radiation layer formed along an edge of the solder resist.

2. The printed circuit board of claim 1, wherein the heat radiation layer is formed of copper, aluminum or an aluminum alloy.

3. The printed circuit board of claim 1, wherein the bump has a circular truncated cone shape in which a diameter increases from one end toward the other end and the other end of which is flat.

4. The printed circuit board of claim 1, wherein the other end of the bump is formed to be flush with an exposed surface of the heat radiation layer.

5. A method of manufacturing a printed circuit board, comprising:
(A) preparing a base substrate having an insulating layer and a circuit layer formed thereon, and stacking a solder resist and a metal layer on the base substrate;
(B) forming an opening to pass through the metal layer and the solder resist so as to expose a pad of the circuit layer;
(C) forming a bump in the opening; and
(D) selectively etching the metal layer so that the metal layer remains only on an edge of the solder resist, thus forming a heat radiation layer.

6. The method of claim 5, wherein (A) comprises:
(A′) preparing a base member having a metal layer and a solder resist applied thereon, preparing a base substrate having an insulating layer and a circuit layer formed thereon, and stacking the base member on the base substrate so that the solder resist and the circuit layer face each other.

7. The method of claim 5, wherein (B) comprises:
(B1) applying a first etching resist on the metal layer, and patterning the first etching resist so that a portion of the lint etching resist corresponding to the pad is opened;
(B2) selectively etching the metal layer which is exposed from the first etching resist, thus forming a window; and
(B3) processing the solder resist exposed from the window thus forming an open portion, so that an opening which passes through the metal layer and the solder resist is formed.

8. The method of claim 5, further comprising (B′) forming a surface treatment layer on an exposed surface of the metal layer or an exposed surface of the pad, after (B).

9. The method of claim 5, wherein (C) comprises:
(C1) disposing a solder paste on one side of the metal layer, and printing the solder paste toward the other side of the metal layer, thus forming the bump in the opening; and
(C2) buffing the solder paste remaining on a surface of the metal layer and on a surface of the bump.

10. The method of claim 5, wherein (D) comprises:
(D1) applying a second etching resist on the metal layer, and patterning the second etching resist so that the second etching resist remains only on an edge of the metal layer;
(D2) selectively etching the metal layer exposed from the second etching resist, thus forming a heat radiation layer; and
(D3) removing the second etching resist pattern.
